(19) United States
(12) Patent Application Publication
(10) Pub. No.: US 2007/0061654 A1
(43) Pub. Date: Mar. 15, 2007

(54) Semiconductor integrated circuit and test method

(75) Inventor: Yoshihiro Shimosawa, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 11/503,287

(22) Filed: Aug. 14, 2006

(30) Foreign Application Priority Data
Aug. 29, 2005 (JP) 2005-247381

(51) Int. Cl. G01R 31/28

(52) U.S. Cl. 714/733

(57) ABSTRACT

A semiconductor integrated circuit includes a memory that operates in synchronization with a first clock and a built-in self-test (BIST) circuit for testing the memory. The BIST circuit includes a test data output circuit for outputting test data as input test data to the memory in synchronization with a second clock, an input circuit for receiving output data from the memory in synchronization with a third clock, and a phase shifter for shifting a phase of the first clock and generating the second clock and the third clock.

### BACKGROUND OF THE INVENTION

1. Field of the Invention

The present invention generally relates to a semiconductor integrated circuit and a test method, and particularly relates to a semiconductor integrated circuit and a test method using a built-in self-test (BIST) circuit.

2. Description of Related Art

A write and read test is necessary for circuits such as a random access memory (RAM) to detect an operational error. In order to promote the efficiency of the test, a test method that connects a dedicated BIST circuit to a RAM for testing is commonly used.

A conventional test method using the BIST circuit is disclosed in Japanese Unexamined Patent Application Publication No. 2004-185691, for example. Referring to FIG. 6, a BIST circuit 21 is connected to a RAM 22. The BIST circuit 21 includes a phase-locked loop (PLL) controller 23 for multiplying a clock, and a high-speed tester 24.

In the method described in Japanese Unexamined Patent Application Publication No. 2004-185691, the PLL controller 23 in the BIST circuit 21 multiplies an input clock and supplies it to the high-speed tester 24. The high-speed tester 24 receives the multiplied clock and outputs a test signal at high speed to the RAM 22. The BIST circuit 21 tests the RAM 22 in this manner.

In order to perform high-speed testing, it would be possible to increase a clock frequency of the BIST circuit. However, if a clock frequency is higher than an actual operation frequency, it is unable to perform a test in accordance with actual operation.

Japanese Unexamined Patent Application Publication No. 2004-212310, for example, discloses a method of performing an operational test at an apparently high clock frequency by shirting a phase of the clock. This method inputs data at a rising edge of a clock whose phase has been shifted by a phase controller, and outputs data at a rising edge of a clock whose phase has not been shifted. The method thereby increases the apparent clock frequency.

As described earlier, the conventional circuit test method fails to perform a test at a higher frequency than a clock frequency. It also fails to perform a test in accordance with an actual operation.

Further, the testing method disclosed in Japanese Unexamined Patent Application Publication No. 2004-212310 is substantially the same as testing a delay of a path between flip-flops, a path that is asynchronous with a clock such as an arithmetic and logical unit (ALU), a RAM and so on. Thus, it is not applicable to the case where a test target is a memory that is synchronous with a clock.

The method disclosed in Japanese Unexamined Patent Application Publication No. 2004-212310 changes a phase difference between flip-flops prior to and subsequent to a test target. It is thus difficult to perform memory testing at different timings for data writing to a memory and data reading from the memory.

In addition, the method disclosed in Japanese Unexamined Patent Application Publication No. 2004-212310 places a phase controller directly on an input clock line to a flip-flop as a user circuit. It is, however, generally not preferred to insert a circuit onto a clock line because an error occurs in an overall circuit upon occurrence of clock skew or the like. Therefore, this method requires an additional step to prevent the occurrence of clock skew or the like due to the inserted phase controller.

### SUMMARY OF THE INVENTION

According to an aspect of the preset invention, there is provided a semiconductor integrated circuit which includes a memory that operates in synchronization with a first clock and a built-in self-test (BIST) circuit for testing the memory. The BIST circuit includes a test data output circuit for outputting test data as input test data to the memory in synchronization with a second clock, an input circuit for receiving output data from the memory in synchronization with a third clock, and a phase shifter for shifting a phase of the first clock and generating the second clock and the third clock. This configuration enables high-speed testing and testing in accordance with actual operation without increasing a clock frequency.

According to another aspect of the preset invention, there is provided a test method for a memory that operates in synchronization with a first clock, which includes shifting a phase of the first clock and generating a second clock and a third clock, outputting test data as input test data to the memory in synchronization with the second clock, and receiving output data from the memory in synchronization with the third clock. This method enables high-speed testing and testing in accordance with actual operation without increasing a clock frequency.

The present invention provides a semiconductor integrated circuit and a test method capable of high-speed testing without increasing a clock frequency.

### BRIEF DESCRIPTION OF THE DRAWINGS

The above and other objects, advantages and features of the present invention will be more apparent from the following description taken in conjunction with the accompanying drawings, in which:

FIG. 1 is a block diagram showing an exemplary configuration of a semiconductor integrated circuit according to an embodiment of the present invention;

FIG. 2A is a view showing an exemplary test data output circuit according to an embodiment of the present invention;

FIG. 2B is a view showing an exemplary input circuit according to an embodiment of the present invention;

FIG. 3 is a waveform chart showing the state of a clock according to an embodiment of the present invention;

FIG. 4 is a waveform chart showing the state of a clock according to a related art;

FIG. 5 is a waveform chart showing the state of a clock according to an embodiment of the present invention; and

FIG. 6 is a block diagram showing a configuration of a tester according to a related art.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

### First Embodiment

A specific configuration of a semiconductor integrated circuit and a test process flow according to a first exemplary embodiment of the present invention are described hereinafter. The case of using a RAM-BIST circuit that tests a RAM is described in the following by way of illustration.

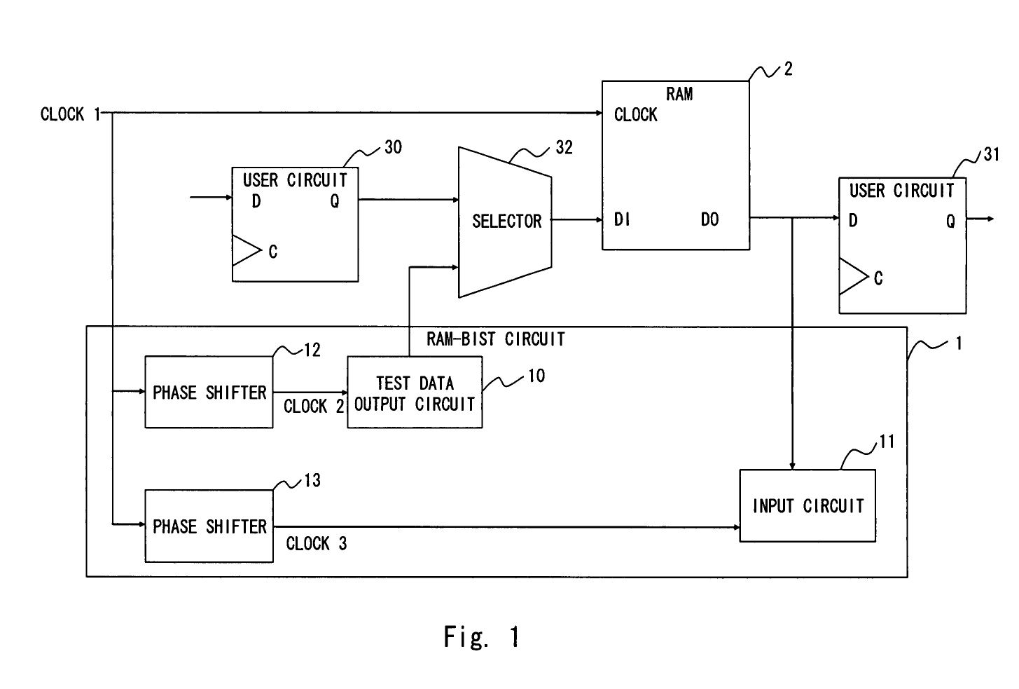

FIG. 1 is a block diagram showing a configuration of a semiconductor integrated circuit according to this embodiment. The integrated circuit includes a RAM-BIST circuit 1, a RAM 2, a user circuit 30, a user circuit 31, and a selector 32. The RAM-BIST circuit 1 is connected to the RAM 2 and performs an operational test on the RAM 2. The RAM-BIST circuit 1 includes a test data output circuit 10, an input circuit 11, a phase shifter 12, and a phase shifter 13.

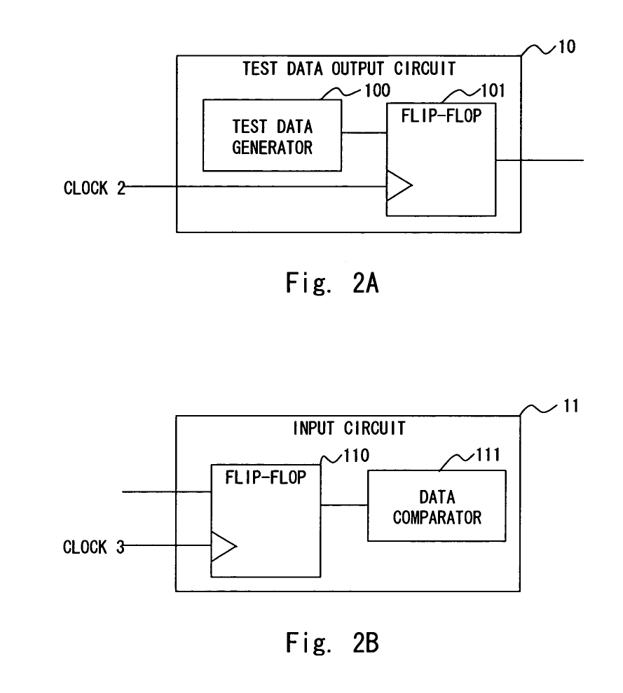

The test data output circuit 10 receives a tester clock as a second clock from the phase shifter 12 and outputs test data to the RAM 2 in accordance with the input tester clock. FIG. 2A shows an example of the test data output circuit 10. As shown in FIG. 2A, the test data output circuit 10 includes a test data generator 100 and a test data output circuit 101.

The test data generator 100 generates test data to be supplied to the RAM 2. The test data output circuit 101 receives a tester clock as the second clock from the phase shifter 12 and further receives the test data from the test data generator 100. In response to the input tester clock, the test data output circuit 101 outputs the input test data to the selector 32. The test data output circuit 101 may employ a conventional test data output circuit.

The input circuit 11 receives a tester clock as a third clock from the phase shifter 13 and receives data from the RAM 2 in response to the input tester clock. FIG. 2B shows an example of the input circuit 11. As shown in FIG. 2B, the input circuit 11 includes an input circuit 110 and a data comparator 111.

The input circuit 110 receives a tester clock as a third clock from the phase shifter 13 and further receives data from the RAM 2 in response to the input tester clock. The input circuit 110 supplies the input data to the data comparator 111. The data comparator 111 compares the data supplied from the input circuit 110 and determines as to whether the data output from the RAM 2 is correct or not. The data comparator 111 may employ a conventional data comparator.

The phase shifter 12 receives a first clock which is indicated as Clock 1 in FIG. 1, shifts the phase of the input first clock, and outputs it as a tester clock as the second clock. A technique for shifting the phase may employ a delay locked loop (DLL) or a phase locked loop (PLL), though the technique it not particularly limited. The tester clock with the shifted phase is supplied to the test data output circuit 10 as the second clock which is indicated as Clock 2 in FIG. 1.

The phase shifter 13 receives a first clock which is indicated as Clock 1 in FIG. 1, shifts the phase of the input first clock, and outputs it as a tester clock as the third clock. A technique for shifting the phase may employ a delay locked loop (DLL) or a phase locked loop (PLL), though the technique is not particularly limited. The tester clock with the shifted phase is supplied to the test input circuit 11 as the third clock which is indicated as Clock 3 in FIG. 1.

The phase shifters are described hereinafter. In this embodiment, a phase is shifted 180 degrees. If the degree of phase shift is restricted to 180°, the state (High/Low) of the clock is inverted, and therefore the phase shift can be implemented using an inverter.

The RAM 2 is a test target, which is a memory to be tested by the RAM-BIST circuit 1 as a tester. This embodiment performs testing by outputting data from the test data output circuit 10 to the RAM 2 and then inputting data from the RAM 2 to the input circuit 11. The RAM 2 receives the first clock indicated as Clock 1 in FIG. 1. The operation of the RAM 2 is performed in response to the first clock indicated as Clock 1 in FIG. 1.

During normal operation, the RAM 2 is connected to the user circuits 30 and 31. Data is input to the RAM 2 from the user circuit 30 and output from the RAM 2 to the user circuit 31. During testing, data is input to the RAM 2 from the test data output circuit 10 rather than the user circuit 30 according to the selection of the selector 32.

The user circuit 30 is used when the test is not performed. The user circuit 30 outputs data to the RAM 2. The data output from the user circuit 30 is input to the RAM 2 through the selector 32.

The user circuit 31 is also used when the test is not performed. The user circuit 31 receives data from the RAM 2. FIG. 1 illustrates only flip-flips of the user circuits 30 and 31, which are the parts directly connected to the RAM 2.

The selector 32 selects one from the data output from the user circuit 30 and the data output from the test data output circuit 10 and supplies the selected data to the RAM 2. The selector 32 selects the data from the test data output circuit 10 during testing periods while it selects the data output from the user circuit 30 during non-testing periods.

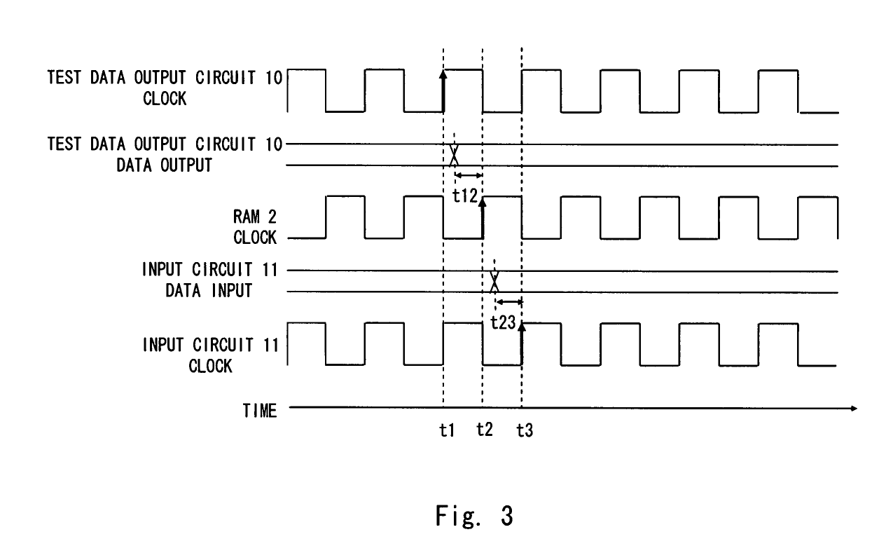

The operation of the clock in this embodiment is described hereinafter with reference to the waveform chart in FIG. 3. “RAM 2 clock” in FIG. 3 indicates the operation clock of the RAM 2, which is a test target clock or the first clock. The tester clocks that are input to the phase shifters 10 and 11 are also the first clock before the phase shift. “Test data output circuit 10 clock” in FIG. 3 indicates a tester clock whose phase is shifted by the phase shifter 12 and that is supplied to the test data output circuit 10, which is the second clock. The test data output circuit 10 operates in response to the “test data output circuit 10 clock”.

“Test data output circuit 10 data output” in FIG. 3 indicates a timing when data is output from the test data output circuit 10. At the timing indicated by the mark “x” at the “test data output circuit 10 data output” in FIG. 3, data is output from the test data output circuit 10 to the RAM 2 through the selector 32.

“Input circuit 11 clock” in FIG. 3 is a tester clock whose phase is shifted by the phase shifter 13 and that is input to the input circuit 11, which is the third clock. The input circuit 11 operates in response to the “input circuit 11 clock”.

“Input circuit 11 data input” in FIG. 3 is a timing when data is input to the input circuit 11 from the RAM 2. At the timing indicated by the mark “x” at the “input circuit 11 data input” in FIG. 3, data from the RAM 2 is input to the input circuit 11.

Flow of data when clock operation is as shown in FIG. 3 is described hereinbelow. The test data output circuit 10 outputs test data to the RAM 2. The test data is output at a rising edge of the “test data output circuit 10 clock” which is indicated by the arrow in FIG. 3. Then, the test data output from the test data output circuit 10 changes. The selector 32 then selects data from the test data output circuit 10, not the user circuit 30, and supplies it to the RAM 2. The data selected by the selector 32 is input to the RAM 2 at a rising edge of the “RAM 2 clock” which is indicated by the arrow in FIG. 3.

Now, it is assumed that test data is output from the test data output circuit 10 to the RAM 2 at the timing t1 shown in FIG. 3, for example. The data output from the test data output circuit 10 changes at the timing indicated by the mark “x” of the “test data output circuit 10 data output” in FIG. 3. The data output from the test data output circuit 10 is actually input to the RAM 2 at the timing when the clock of the RAM 2 rises after t1, which is the timing t2 shown in FIG. 3.

It is also assumed that data is output from the RAM 2 to the input circuit 11 at the timing t2 shown in FIG. 3. The data output from the RAM 2 changes at the timing indicated by the mark “x” of the “input circuit 11 data input” in FIG. 3. The data output from the RAM 2 is actually input to the circuit 11 at the timing when the clock of the input circuit 11 rises after t2, which is the timing t3 shown in FIG. 3.

As described in the foregoing, if the phase is shifted using the phase shifters 12 and 13, a setup time from the test data output circuit 10 to the RAM 2 during data writing is t12 shown in FIG. 3. A setup time from the RAM 2 to the input circuit 11 is t23 shown in FIG. 3.

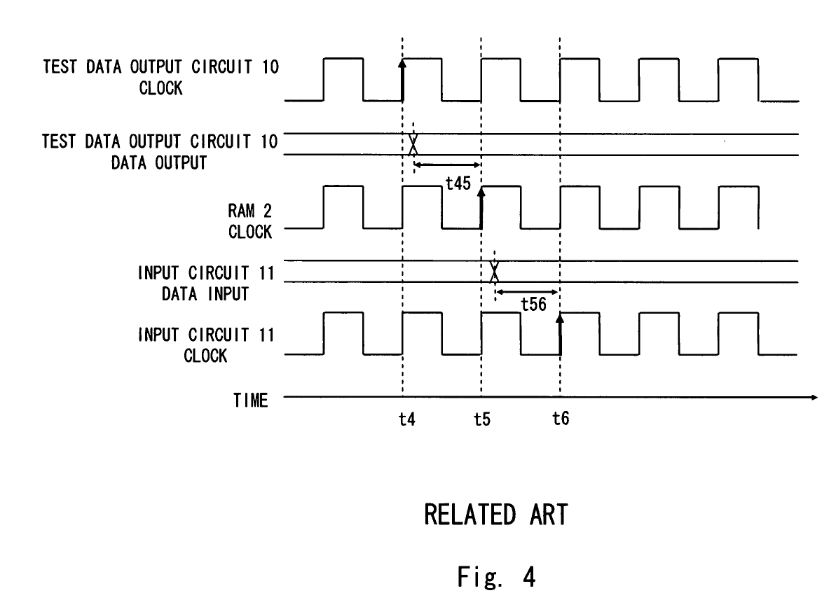

On the other hand, the setup time without using the phase shifters 12 and 13 is t45 and t56 shown in FIG. 4, respectively. Comparing FIG. 3 and FIG. 4, it is obvious that the phase shift using the phase shifters 12 and 13 enables reduction of the setup time to achieve high-speed testing of the RAM 2.

### Second Embodiment

According to another embodiment of the present invention, in addition to achieving high-speed testing of a RAM, it is possible to adjust a setup time in light of a path delay between a user flip-flop and a RAM or the like and perform testing under the same conditions as for the user flip-flop by using the phase shifter.

The configuration of the tester of the second embodiment is substantially the same as that of the first embodiment and thus not described herein. The second embodiment, however, is different from the first embodiment in that the phase shifters 12 and 13 do not employ PLL rather than DLL to be capable of detailed phase shift.

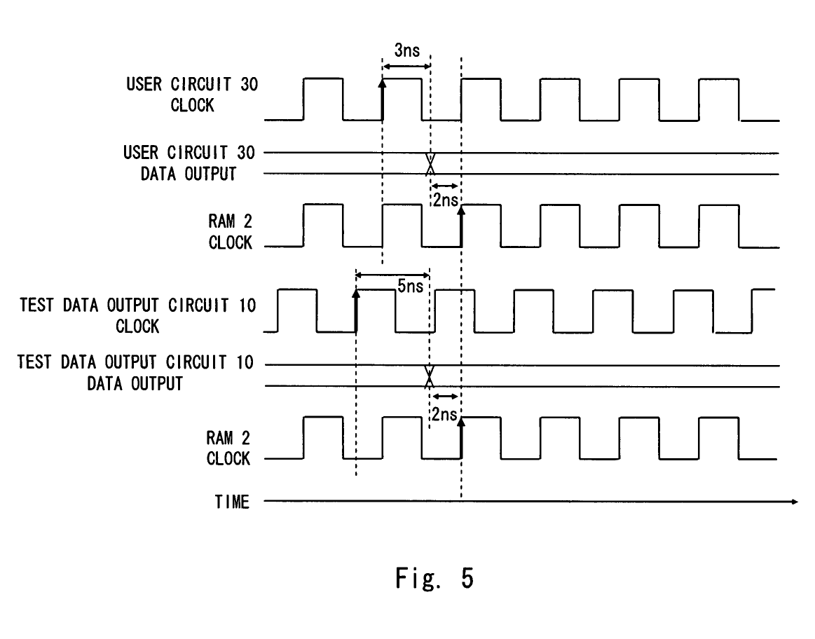

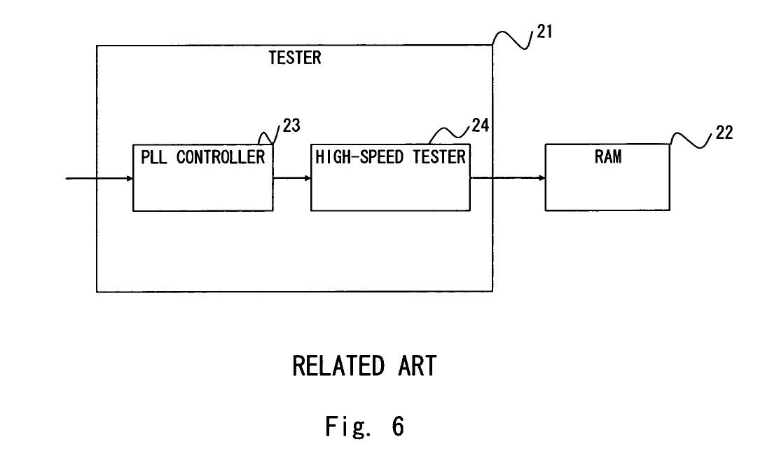

The clock operation of this embodiment is described hereinafter with reference to the waveform chart in FIG. 5. “RAM 2 clock” in FIG. 5 indicates the operation clock of the RAM 2, which is a test target clock or the first clock. The tester clocks that are input to the user circuits 30 and 31 are also the first clock before the phase shift.

As shown in the waveform chart of FIG. 5, a path delay time until the data output from the user circuit 30 can be input to the RAM 2 is 3 ns. Further, a setup time of the RAM 2 takes 2 ns.

On the other hand, a path delay time until the data output from the test data output circuit 10 can be input to the RAM 2 is 5 ns. Further, a setup time of the RAM 2, which is a time required to actually input the data that is output from the test data output circuit 10 to the RAM 2, takes 2 ns.

These delay times can be measured in advance using an exclusive device or the like. If the measurement result reaches a value as shown in FIG. 5, the phase of the tester clock that is input to the test data output circuit 10 is changed, thereby matching the timing to input the data output from the user circuit 30 and the timing to input the data output from the test data output circuit 10 to the RAM 2.

The phase to be shifted is determined by calculating a difference in delay time. In the example of FIG. 5, the phase shift corresponding to 2 ns, which is a difference of 5 ns and 3 ns, is performed. Thus, the phase is shifted so that a time difference between a rising edge of the test data output circuit 10 and the rising edge of the user circuit 30 is 2 ns.

As described in the foregoing, it is possible to perform testing in which a timing to input data to the RAM 2 is the same as the timing of an actual user circuit by shifting the phase in light of a difference in setup time between a user flip-flop operated by an actual user circuit and a flip-flop operated by a tester.

It is apparent that the present invention is not limited to the above embodiment that may be modified and changed without departing from the scope and spirit of the invention.

What is claimed is:

1. A semiconductor integrated circuit comprising:
a memory that operates in synchronization with a first clock; and
a built-in self-test (BIST) circuit for testing the memory, the BIST circuit comprising:
a test data output circuit for outputting test data as input test data to the memory in synchronization with a second clock;
an input circuit for receiving output data from the memory in synchronization with a third clock; and
a phase shifter for shifting a phase of the first clock and generating the second clock and the third clock.

2. The semiconductor integrated circuit according to claim 1, wherein the phase shifter generates the second clock and the third clock that are different from each other.

3. The semiconductor integrated circuit according to claim 1, wherein a phase difference between the first clock and the second clock is determined based on a path delay time between a user circuit for outputting data to the memory and the memory, and a path delay time between the test data output circuit and the memory.

4. The semiconductor integrated circuit according to claim 1, wherein a phase difference between the first clock and the third clock is determined based on a path delay time between a user circuit for receiving data from the memory and the memory, and a path delay time between the test data output circuit and the memory.

5. The semiconductor integrated circuit according to claim 1, wherein the phase shifter is composed of a phase locked loop (PLL) or a delay locked loop (DLL).

6. A test method for a memory that operates in synchronization with a first clock, comprising:
shifting a phase of the first clock and generating a second clock and a third clock;
outputting test data as input test data to the memory in synchronization with the second clock; and
receiving output data from the memory in synchronization with the third clock.

7. The test method according to claim 6, wherein the second clock and the third clock are different from each other.

8. The test method according to claim 6, wherein a phase difference between the first clock and the second clock is determined based on a path delay time between a user circuit for outputting data to the memory and the memory, and a path delay time between the test data output circuit and the memory.

9. The test method according to claim 6, wherein a phase difference between the first clock and the third clock is determined based on a path delay time between a user circuit for receiving data from the memory and the memory, and a path delay time between the test data output circuit and the memory.
